(19) United States
(12) Patent Application Publication
(10) Pub. No.: US 2024/0235389 A1
(43) Pub. Date: Jul. 11, 2024

(54) POWER CONVERTER SYSTEM WITH CASCADED POWER STAGES AND SHARING OF INFORMATION BETWEEN POWER STAGES FOR CONTROL

(71) Applicant: Cirrus Logic International Semiconductor Ltd., Edinburgh (GB)

(72) Inventors: Hasnain AKRAM, Austin, TX (US); Graeme G. MACKAY, Austin, TX (US); Jason W. LAWRENCE, Austin, TX (US); Ilija JERGOVIC, Austin, TX (US); Eric J. KING, Austin, TX (US); Thomas H. HOFF, Austin, TX (US); Paulo RAYMUNDO SILVA, Austin, TX (US)

(73) Assignee: Cirrus Logic International Semiconductor Ltd., Edinburgh (GB)

(21) Appl. No.: 18/458,331

(22) Filed: Aug. 30, 2023

Related U.S. Application Data
(60) Provisional application No. 63/438,401, filed on Jan. 11, 2023.

(51) Int. Cl. H02M 3/07; H02M 1/00

(52) U.S. Cl. CPC H02M 3/07; H02M 1/007; H03F 3/183

(57) ABSTRACT

In accordance with embodiments of the present disclosure, a power converter system may comprise a plurality of power converter stages in a cascaded arrangement, the power converter stages comprising at least a first power converter stage and a second power converter stage configured to modify an operational state and/or an operational mode of the second power converter stage responsive to feedforward information associated with the first power converter stage.

### RELATED APPLICATION

The present disclosure claims priority to U.S. Provisional Application No. 63/438,401, filed Jan. 11, 2023, and incorporated by reference herein in its entirety.

### FIELD OF DISCLOSURE

The present disclosure relates in general to circuits for electronic devices, including without limitation personal audio devices such as wireless telephones and media players, and more specifically, sharing of information between cascaded power stages and controlling one or more of such power stages based on the shared information.

### BACKGROUND

Personal audio devices, including wireless telephones, such as mobile/cellular telephones, cordless telephones, mp3 players, and other consumer audio devices, are in widespread use. Such personal audio devices may include circuitry for driving a pair of headphones, one or more speakers, haptic actuators, camera stabilization motors, and/or other load. Such circuitry often includes a driver including a power amplifier for driving an output signal to such loads. Oftentimes, a power converter may be used to provide a supply voltage to a power amplifier in order to amplify a signal driven to speakers, headphones, other transducers, or other loads. A switching power converter is a type of electronic circuit that converts a source of power from one direct current (DC) voltage level to another DC voltage level. Examples of such switching DC-DC converters include but are not limited to a boost converter, a buck converter, a buck-boost converter, an inverting buck-boost converter, and other types of switching DC-DC converters. Thus, using a power converter, a DC voltage such as that provided by a battery may be converted to another DC voltage used to power the power amplifier. A power converter may be used to provide supply voltage rails to one or more components in a device. A power converter may also be used in other applications besides driving audio transducers, such as driving haptic actuators or other electrical or electronic loads. Further, a power converter may also be used in charging a battery from a source of electrical energy (e.g., an AC-to-DC adapter).

### SUMMARY

In accordance with the teachings of the present disclosure, one or more disadvantages and problems associated with existing approaches and architectures of power converter systems may be reduced or eliminated.

In accordance with embodiments of the present disclosure, a power converter system may comprise a plurality of power converter stages in a cascaded arrangement, the power converter stages comprising at least a first power converter stage and a second power converter stage configured to modify an operational state and/or an operational mode of the second power converter stage responsive to feedforward information associated with the first power converter stage.

In accordance with these and other embodiments of the present disclosure, a method may be provided in a power converter system comprising a plurality of power converter stages in a cascaded arrangement, and wherein the power converter stages comprise at least a first power converter stage and a second power converter stage. The method may include modifying an operational state and/or an operational mode of the second power converter stage responsive to feedforward information associated with the first power converter stage.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates a block diagram of selected components of an example power converter system, in accordance with embodiments of the present disclosure;

FIG. 1B illustrates a block diagram of selected components of another example power converter system, in accordance with embodiments of the present disclosure;

FIG. 2 illustrates a block diagram of selected components of an example power converter system in which a first power converter stage is implemented by a gain normalization block and an inductive converter, a second power converter stage is implemented by a charge pump, and an information controller is implemented with a ratio controller, in accordance with embodiments of the present disclosure;

FIG. 3 illustrates a block diagram of selected components of an example power converter system in which a first power converter stage is implemented by an inductive converter and a second power converter stage is implemented by a charge pump, in accordance with embodiments of the present disclosure;

FIG. 4 illustrates a block diagram of selected components of an example power converter system in which a first power converter stage is implemented by an inductive converter, a second power converter stage is implemented by a charge pump, and an information controller is implemented with an efficiency controller, in accordance with embodiments of the present disclosure;

FIG. 5 illustrates a graphical representation of example control of parameters of an inductive converter and a charge pump of the power converter system of FIG. 4 as a function of the output power of the inductive converter, in accordance with embodiments of the present disclosure;

FIG. 6 illustrates a graphical representation of example control of a charge pump ratio of the charge pump depicted in FIG. 4 as a function of a supply voltage, in accordance with embodiments of the present disclosure;

FIG. 7 illustrates a block diagram of selected components of an example power converter system in which a first power converter stage is implemented by a first inductive converter and a second power converter stage is implemented by a second inductive converter, in accordance with embodiments of the present disclosure;

FIG. 8A illustrates a graphical representation of particular parameters associated with the power converter system of FIG. 7 in the absence of communication of power limiting information, in accordance with embodiments of the present disclosure;

FIG. 8B illustrates a graphical representation of particular parameters associated with the power converter system of FIG. 7 in the presence of communication of power limiting information, in accordance with embodiments of the present disclosure; and

FIG. 9 illustrates a block diagram of selected components of an example power converter system in which a first power converter stage is implemented by a first inductive converter and a second power converter stage is implemented by a second inductive converter, in accordance with embodiments of the present disclosure.

### DETAILED DESCRIPTION

For a given architecture for a power converter, it may be desirable to obtain optimal efficiency across voltage conversion ratios for a given solution size. The use of a multi-level inductive converter may advantageously provide a variable voltage conversion ratio, but its efficiency curve may have optimal points as a function of conversion ratio (e.g., a three-level converter efficiency may be decreased for conversion ratios of less than 50%). Further, a fixed-ratio charge pump may maintain high efficiency at integer multiples of conversion ratios, but does not support variable voltage conversion ratios.

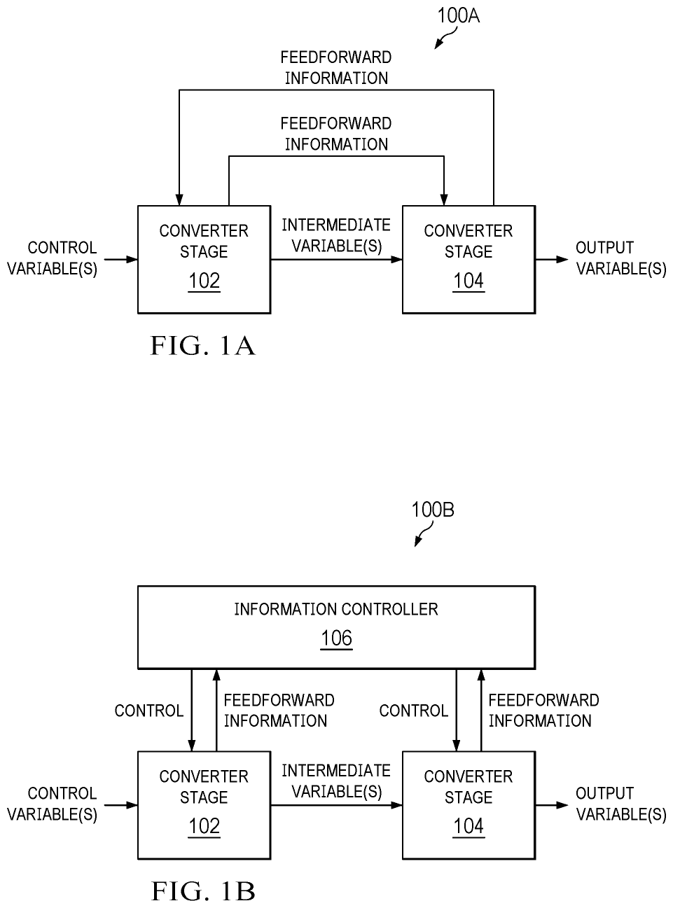

In certain applications, it may be beneficial to cascade two or more power conversion stages, rather than performing power conversion in a single stage. As further described in greater detail below, the performance (e.g., transient response, efficiency, etc.) of one or both of the power conversion stages may benefit from sharing information present in one power stage with the other. FIGS. 1A and 1B provide illustrations of examples of such power converter systems. FIG. 1A illustrates a block diagram of selected components of an example power converter system 100A for generating one or more output variables (e.g., a regulated current or voltage) as a function of one or more control variables (e.g., a control signal indicative of a desired regulated current or voltage), in accordance with embodiments of the present disclosure. As shown in FIG. 1A, a first power converter stage 102 may receive one or more control variables as input and generate one or more intermediate variables (e.g., an intermediate voltage or current) received by a second power converter stage 104 which may generate the one or more output variables (e.g., an output voltage or current) as a function of the one or more intermediate variables. Further as shown in FIG. 1A, first power converter stage 102 may communicate feedforward information regarding first power converter stage 102 to second power converter stage 104, and second power converter stage 104 may communicate feedforward information regarding second power converter stage 104 to first power converter stage 102. As a result, operation of one or both of first power converter stage 102 and second power converter stage 104 may be controlled based on feedforward information received regarding the other power converter. Accordingly, power converter system 100A includes decentralized sharing of feedforward information between first power converter stage 102 and second power converter stage 104.

FIG. 1B illustrates a block diagram of selected components of another example power converter system 100B for generating one or more output variables (e.g., a regulated current or voltage) as a function of one or more control variables (e.g., a control signal indicative of a desired regulated current or voltage), in accordance with embodiments of the present disclosure. Power converter system 100B may be similar in many respects to power converter system 100A, except that power converter system 100B may also include an information controller 106 communicatively coupled to first power converter stage 102 and second power converter stage 104 and configured to receive feedforward information from one or both of first power converter stage 102 and second power converter stage 104 and control one or both of first power converter stage 102 and second power converter stage 104 based on feedforward information received regarding the other power converter stage. Accordingly, power converter system 100B includes centralized sharing of feedforward information between first power converter stage 102 and second power converter stage 104.

As used herein, “feedforward information” communicated from a converter stage may include any information associated with the converter stage other than the intermediate variable(s) (e.g., current or voltage) and output variable(s) (e.g., current or voltage) generated by such converter stage (e.g., information external to a signal path from control variable(s) to intermediate variable(s) of the cascaded converter stages) and other than any other information readily available to the other converter in the absence of feedforward information. For example, and without limitation, “feedforward information” may include a change in one or more of an operational state, an operational mode, and a control variable of the first power converter stage.

Either power converter stage 102, 104 may comprise any suitable system, device, or apparatus for performing power conversion, including without limitation an inductive power converter (e.g., boost converter, buck converter, or multi-level power converter), a charge pump, and/or any other suitable power conversion circuit.

In power converter systems 100A and 100B, one or both of first power converter stage 102 and second power converter stage 104 may have at least two operational modes. Further, a power converter stage 102 or 104 may have different configuration settings (e.g., dividers, gains, modulation type, conversion ratio, number of active phases/operational blocks, bandwidth) in different operational modes. For example, when a power converter stage comprises an inductive power converter, such configuration settings may be in operation in either of a pulse-frequency modulation mode or pulse-width modulation mode, may be in operation in a steady-state configuration or high-bandwidth configuration, may and/or may be in operation among a number of discrete or continuous frequency levels, and/or a number of parallel power converter phases activated. As another example, when a power converter stage comprises a charge pump, such configuration setting may include a charge pump ratio (e.g., 1:1, 2:1, or 3:1).

In power converter systems 100A and 100B, one or both of first power converter stage 102 and second power converter stage 104 may have at least two operational states. Further, a power converter stage 102 or 104 may have different state parameters (e.g., memory variables, integrator variables, duty cycle etc.) in different operational states.

As described in greater detail below with reference to a number of example embodiments, in operation, a second power converter stage may be configured to force a modification to its own operational state and/or operational mode responsive to a change in one or more of an operational state, an operational mode, and a control variable of a first power converter stage. In some embodiments, the first power converter stage may communicate feedforward information regarding the change in one or more of an operational state, an operational mode, and a control variable of a first power converter stage. In these and other embodiments, the second power converter's forced modification to its own operational state and/or operational mode may occur substantially contemporaneously with a change in operational state, operational mode, and/or control variable(s) of the first power converter stage. In this context, “substantially contemporaneously” may mean almost immediately, constrained only by practical delays in transmission of feedforward information indicative of the change in one or more of the operational state, an operational mode, and a control variable of the first power converter stage, time needed by information controller 106 to process the shared feedforward information, and/or time needed for the second power converter stage to react to the feedforward information or control signals received from information controller 106.

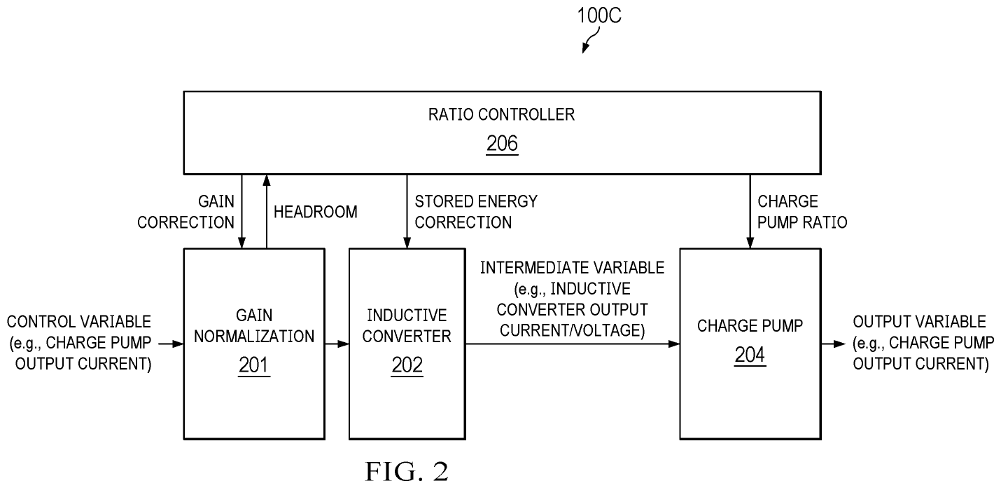

FIG. 2 illustrates a block diagram of selected components of an example power converter system 100C in which first power converter stage 102 is implemented by a gain normalization block 201 and an inductive converter 202, second power converter stage 104 is implemented by a charge pump 204, and information controller 106 is implemented with a ratio controller 206, in accordance with embodiments of the present disclosure. In example power converter system 100C, ratio controller 206 may perform centralized sharing of feedforward information regarding amount of available voltage headroom of gain normalization block 201 in order to dynamically control a charge pump ratio of charge pump 204, a gain correction factor for gain normalization block 201 (which may be an inverse of the charge pump ratio), and a stored energy correction factor for inductive converter 202. The architecture of power converter system 100C may enable the provision of optimal conversion ratios based on the available voltage headroom to maximize power efficiency of power converter system 100C. Such architecture may further enable instantaneous changes to the charge pump ratio without risk of high currents and thermal overload, provided the input capacitor of charge pump 204 is sufficiently small.

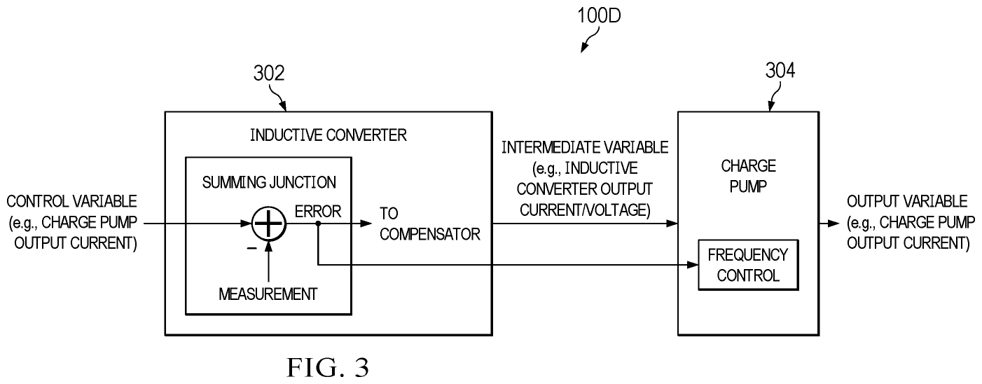

FIG. 3 illustrates a block diagram of selected components of an example power converter system 100D in which first power converter stage 102 is implemented by an inductive converter 302 and second power converter stage 104 is implemented by a charge pump 304, in accordance with embodiments of the present disclosure. In example power converter system 100D, an error present within a closed control loop of inductive converter 302 (e.g., as calculated by a summing junction based on a difference of a control variable and a measurement of the quantity regulated by the control variable) may be communicated to charge pump 304 and used by charge pump 304 to control switching frequency of switches within charge pump 304 (e.g., by a frequency control block of charge pump 304), in order to optimize a transient response of power converter system 100D. Thus, for large transient events, which may lead to an increase in the magnitude of the error, charge pump 304 may respond by increasing its switching frequency, which may allow for a faster dynamic response in order to decrease the error while maintaining a lower switching frequency (and thus higher power efficiency) under steady-state conditions in which the magnitude of the error is at or near zero. Stated another way, charge pump 304 may be “sped up” when the error within inductive converter 302 is high, essentially decreasing a group delay through charge pump 304 and enabling a better dynamic response to the increased error, at the cost of reduced power efficiency.

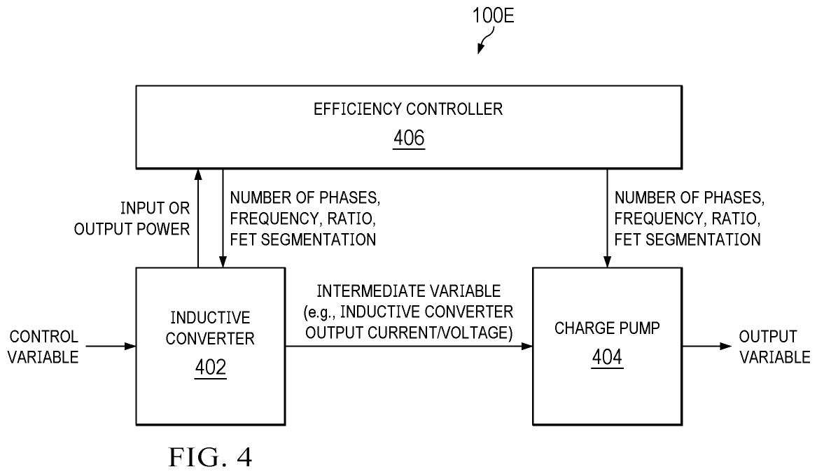

FIG. 4 illustrates a block diagram of selected components of an example power converter system 100E in which first power converter stage 102 is implemented by an inductive converter 402, second power converter stage 104 is implemented by a charge pump 404, and information controller 106 is implemented with an efficiency controller 406, in accordance with embodiments of the present disclosure. In power converter system 100E, efficiency controller 406 may based on receipt of feedforward information from inductive converter 402 indicative of an input power or output power of inductive converter 402, maximize steady-state efficiency of power converter system 100E at a given operating point by controlling one or more parameters associated with inductive converter 402 and/or charge pump 404. Examples of such one or more parameters may include the number of active phases of inductive converter 402 and/or charge pump 404, a frequency of operation of inductive converter 402 and/or charge pump 404, field-effect transistor (FET) segmentation of switches of inductive converter 402 and/or charge pump 404, and/or a charge pump ratio of charge pump 404.

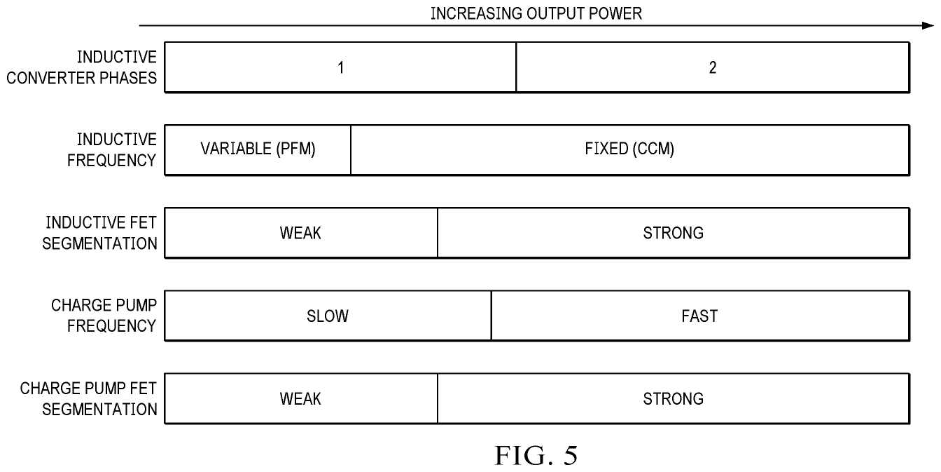

FIG. 5 illustrates a graphical representation of example control of parameters of inductive converter 402 and charge pump 404 as a function of the output power of inductive converter 402, in accordance with embodiments of the present disclosure. For example, as output power of inductive converter 402 increases, efficiency controller 406 may increase the number of phases of inductive converter 402, modify the inductive frequency of inductive converter 402 from a variable frequency using pulse-frequency modulation (PFM) to a fixed frequency using pulse-width modulation in a continuous conduction mode, increase segmentation of FETs of inductive converter 402 from weak to strong, increase a switching frequency of charge pump 404, and increase segmentation of FETs of charge pump 404 from weak to strong. For purposes of clarity and exposition, the example of FIG. 5 assumes two phases for inductive converter 402, two levels of FET segmentation, and two charge pump frequencies. However, it is understood that inductive converter 402 may have any suitable number of phases, inductive converter 402 and/or charge pump 404 may have any suitable levels of FET segmentation, and charge pump 404 may have any suitable number of switching frequencies.

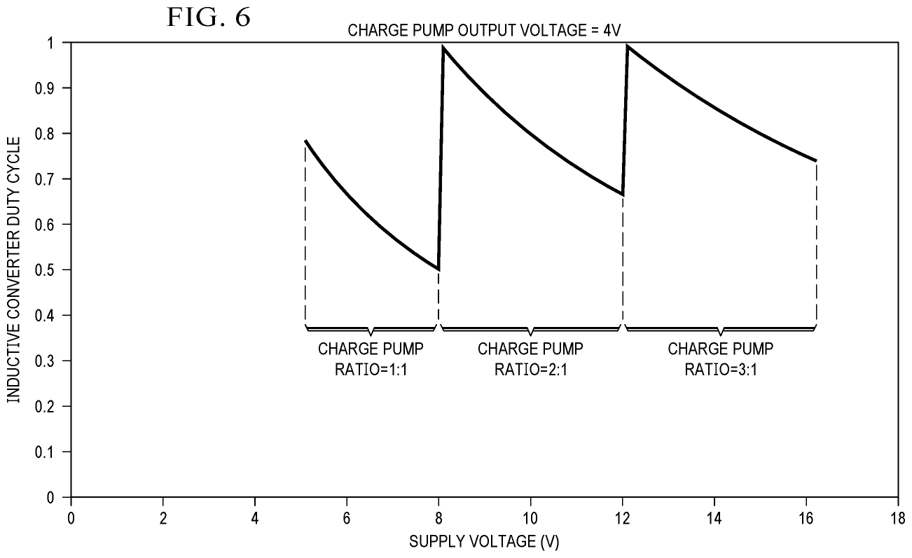

FIG. 6 illustrates a graphical representation of example control of a charge pump ratio of charge pump 404 as a function of an input supply voltage to inductive converter 402, in accordance with embodiments of the present disclosure. In the example of FIG. 6, efficiency controller 406 may control the charge pump ratio of charge pump 404 to maintain a duty cycle of inductive converter 402 as close to 1 as possible in order to maximize efficiency. As shown in FIG. 6, as supply voltage increases, efficiency controller 406 transitions the charge pump ratio from 1:1 to 2:1 and from 2:1 to 3:1 as soon as possible while still maintaining duty cycle of inductive converter 402 below 1.

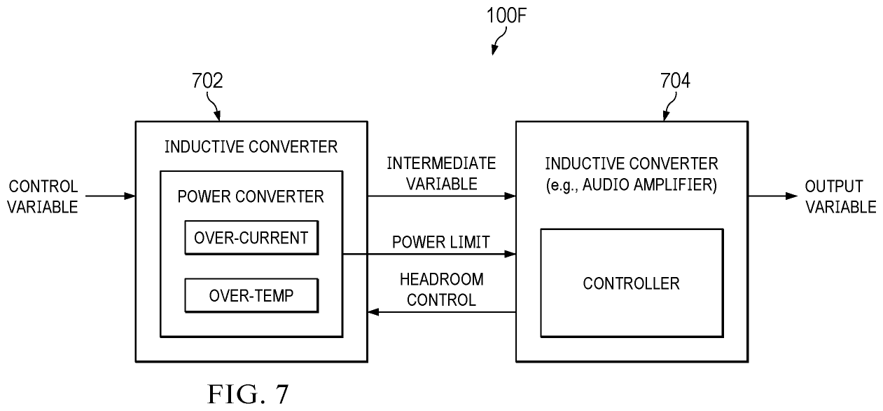

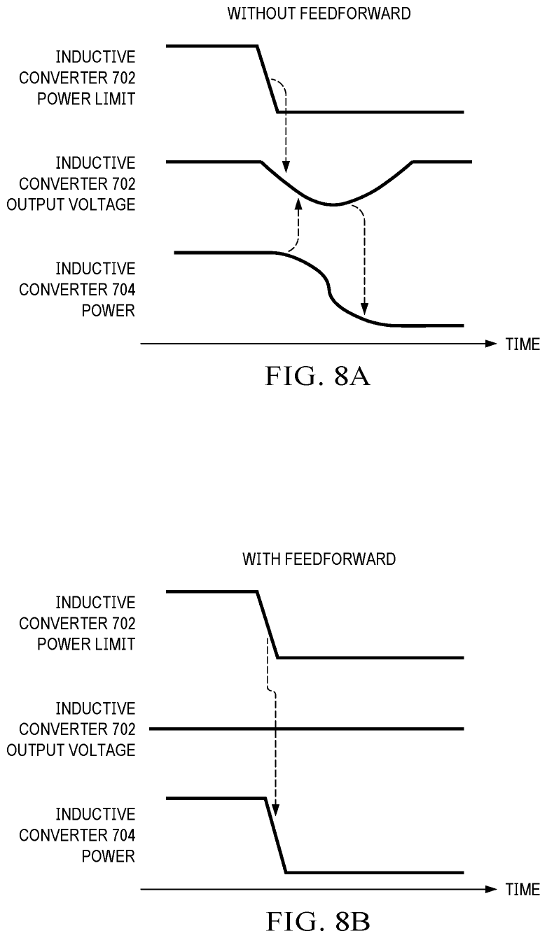

FIG. 7 illustrates a block diagram of selected components of example power converter system 100F in which first power converter stage 102 is implemented by a first inductive converter 702 and second power converter stage 104 is implemented by a second inductive converter 704, in accordance with embodiments of the present disclosure. In particular embodiments, inductive converter 704 may comprise an audio amplifier. As shown in FIG. 7, inductive converter 702 may limit power drawn by inductive converter 702 or power generated by inductive converter 702, for example to prevent an over-current scenario (e.g., in which inductive converter 702 draws an excessive current) or an over-temperature scenario (e.g., in which power converter system 100F exceeds a threshold temperature). In the absence of communication between inductive converters 702 and 704, such power limiting may cause droop in the voltage output by inductive converter 702, which in turn may reduce a headroom for inductive converter 704, as shown in FIG. 8A. Inductive converter 704 must respond to such reduced headroom in order to avoid degraded performance. In embodiments in which inductive converter 704 is an audio amplifier, such reduced performance may result in distortion, clipping, and/or other undesirable audio artifacts. On the other hand, by communication of the power limiting information from inductive converter 702 to inductive converter 704, inductive converter 704 may preemptively modify its power utilization and maintain power balance between inductive converter 702 and inductive converter 704, as shown in FIG. 8B, instead of reacting to the decrease in the output voltage of power converter 702.

In addition, inductive converter 704 may directly provide its headroom requirements to inductive converter 702, which may allow inductive converter 702 to set its output voltage to maximize efficiency while maintaining sufficient headroom for inductive converter 704 at any given operating point.

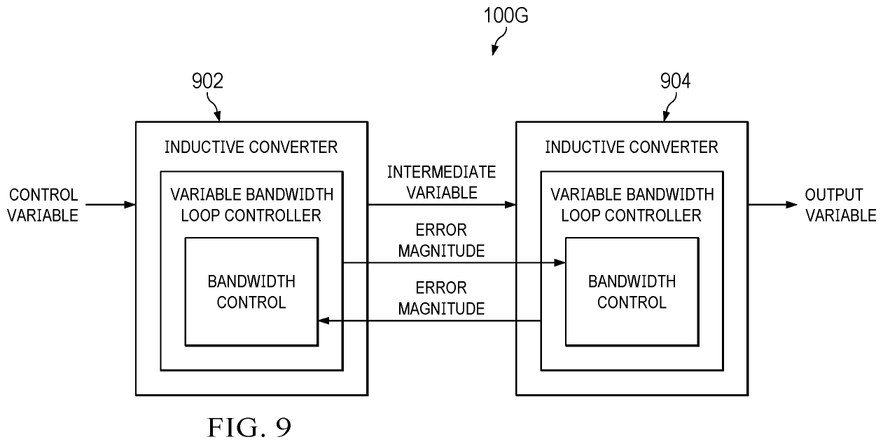

FIG. 9 illustrates a block diagram of selected components of example power converter system 100G in which first power converter stage 102 is implemented by a first inductive converter 902 and second power converter stage 104 is implemented by a second inductive converter 904, in accordance with embodiments of the present disclosure. As shown in FIG. 9, each of inductive converter 902 and inductive converter 904 may include its own variable bandwidth loop controller configured to control the bandwidth of its respective control loop. In example power converter system 100G, a first error present within a closed control loop of inductive converter 902 may be communicated to inductive converter 904 and used by inductive converter 902 to control a bandwidth of inductive converter 904, and a second error present within a closed control loop of inductive converter 904 may be communicated to inductive converter 902 and used by inductive converter 902 to control a bandwidth of inductive converter 902. Thus, based on a high-frequency or transient event occurring in one of inductive converter 902 and inductive converter 904, the other inductive converter may react by modifying its bandwidth to respond, and thus may allow for trading off steady-state requirements (e.g., low noise, low power) for dynamic requirements (e.g., fast settling).

Power converter systems 100 (e.g., power converters 100A-100G) disclosed herein may be implemented within a larger system, and may be used for any suitable purpose. For example, a power converter system 100 may be used to provide supply voltage rails to one or more components in an electronic device, including without limitation providing voltage supply rails for drivers configured to drive audio transducers, haptic actuators, and/or other electrical and/or electronic loads. As another example, a power converter may also be used in charging a battery from a source of electrical energy (e.g., an AC-to-DC adapter).

In the various power converter systems 100 depicted herein, the power converter systems 100 may buck or boost from input to output, and in some embodiments, the order of the depicted stages may be reversed. Further, inductive converter stages (e.g., inductive converter stages 302, 402, 702, 704, 902, and 904) described herein may include any suitable inductive-based power converter including one or more power inductors and one or more switches, including without limitation a buck converter, a boost converter, and a multi-level converter.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A power converter system comprising a plurality of power converter stages in a cascaded arrangement, the power converter stages comprising at least:
a first power converter stage; and
a second power converter stage configured to modify an operational state and/or an operational mode of the second power converter stage responsive to feedforward information associated with the first power converter stage.

2. The power converter system of claim 1, wherein the feedforward information comprises a change in one or more of an operational state, an operational mode, and a control variable of the first power converter stage.

3. The power converter system of claim 2, wherein the second power converter stage is configured to modify its own operational state and/or operational mode substantially contemporaneously with the change in one or more of the operational state, the operational mode, and the control variable of the first power converter stage.

4. The power converter system of claim 1, wherein:
the first power converter stage is configured to communicate feedforward information regarding the first power converter stage; and
the second power converter stage is configured to modify its own operational state and/or operational mode responsive to receipt of the feedforward information.

5. The power converter system claim 4, further comprising an information controller communicatively coupled to the first power converter stage and the second power converter stage and configured to:
receive the feedforward information from the first power converter stage; and
responsive to the feedforward information, communicate one or more control signals to the second power converter stage to force the second power converter stage to modify its operational state and/or operational mode responsive to receipt of the one or more control signals.

6. The power converter system of claim 1, wherein the first power converter stage is upstream of the second power converter stage in the cascaded arrangement.

7. The power converter system of claim 1, wherein the second power converter stage is upstream of the first power converter stage in the cascaded arrangement.

8. The power converter system of claim 1, wherein the first power converter stage comprises either a capacitive power converter or an inductive power converter.

9. The power converter system of claim 1, wherein the second power converter stage comprises either a capacitive power converter or an inductive power converter.

10. The power converter system of claim 1, wherein modification of operational state and/or operational mode of the second power converter stage comprises a change in number of phases enabled in the second power converter stage, a charge pump ratio of the second power converter stage, a switching frequency of the second power converter stage, a switching duty cycle of the second power converter stage, a switch segmentation of the second power converter stage, and a state variable of the second power converter stage.

11. The power converter system of claim 1, wherein:
the first power converter stage is an inductive converter in combination with a gain element;
the second power converter stage is a charge pump;
the feedforward information is indicative of a change of available headroom of the gain element; and
the second power converter stage modifies its charge pump ratio in response to a change in the available headroom.

12. The power converter system of claim 11, wherein a gain of the gain element is changed to compensate for modification of the charge pump ratio.

13. The power converter system of claim 1, wherein:
the first power converter stage is an inductive converter;
the second power converter stage is a charge pump;
the feedforward information is indicative of a change of an error within a control loop of the inductive converter; and
the second power converter stage modifies its switching frequency in response to a change in available headroom.

14. The power converter system of claim 1, wherein:
the first power converter stage is an inductive converter;
the second power converter stage is a charge pump;
the feedforward information is indicative of a change of a power consumption associated with the inductive converter; and
the second power converter stage modifies one or more of its charge pump ratio, number of active phases, switching frequency, and switch segmentation in response to a change in the power consumption.

15. The power converter system of claim 14, wherein the inductive converter modifies one or more of its number of active phases, switching frequency, and switch segmentation in response to a change in the power consumption.

16. The power converter system of claim 1, wherein:
the first power converter stage is a first inductive converter;
the second power converter stage is a second inductive converter;
the feedforward information is indicative of a change of a power limit setting associated with the first inductive converter; and
the second power converter stage modifies its power utilization to maintain power balance between the first inductive converter and the second inductive converter in response to a change in the power limit setting.

17. The power converter system of claim 16, wherein:
the second inductive converter is further configured to communicate its headroom requirements to the first inductive converter; and
the first inductive converter is further configured to set its output voltage in response to a change in the headroom requirements in order to maximize efficiency while maintaining sufficient headroom for the second inductive converter.

18. The power converter system of claim 16, wherein the second inductive converter comprises an audio amplifier.

19. The power converter system of claim 1, wherein:
the first power converter stage is a first inductive converter;
the second power converter stage is a second inductive converter;
the feedforward information is indicative of a change of an error associated within a control loop of the first inductive converter; and
the second power converter stage modifies its bandwidth in response to a change in the error.

20. The power converter system of claim 19, wherein:
the second inductive converter is further configured to communicate to the first inductive converter a second error associated with a second control loop of the second inductive converter; and
the first inductive converter is further configured to modify its bandwidth in response to a change in the second error.

21. The power converter system of claim 1, wherein:
the first power converter stage is an inductive converter;
the second power converter stage is a charge pump; and
the modification comprises a modification of a charge pump ratio of the charge pump.

22. The power converter system of claim 1, wherein:
the first power converter stage is a charge pump;
the second power converter stage is an inductive converter; and
the modification comprises a modification of a state variable of the inductive converter.

23. A method comprising, in a power converter system comprising a plurality of power converter stages in a cascaded arrangement, and wherein the power converter stages comprise at least a first power converter stage and a second power converter stage:
modifying an operational state and/or an operational mode of the second power converter stage responsive to feedforward information associated with the first power converter stage.

24. The method of claim 23, wherein the feedforward information comprises a change in one or more of an operational state, an operational mode, and a control variable of the first power converter stage.

25. The method of claim 24, further comprising modifying the operational state and/or operational mode of the second power converter stage substantially contemporaneously with the change in one or more of the operational state, the operational mode, and the control variable of the first power converter stage.

26. The method of claim 23, further comprising:
communicating, by the first power converter stage, feedforward information regarding the first power converter stage; and
modifying, by the second power converter stage, its own operational state and/or operational mode responsive to receipt of the feedforward information.

27. The method claim 26, further comprising:
receiving, by an information controller communicatively coupled to the first power converter stage and the second power converter stage and configured to, the feedforward information from the first power converter stage; and
responsive to the feedforward information, communicating, by the information controller, one or more control signals to the second power converter stage to force the second power converter stage to modify its operational state and/or operational mode responsive to receipt of the one or more control signals.

28. The method of claim 23, wherein the first power converter stage is upstream of the second power converter stage in the cascaded arrangement.

29. The method of claim 23, wherein the second power converter stage is upstream of the first power converter stage in the cascaded arrangement.

30. The method of claim 23, wherein the first power converter stage comprises either a capacitive power converter or an inductive power converter.

31. The method of claim 23, wherein the second power converter stage comprises either a capacitive power converter or an inductive power converter.

32. The method of claim 23, wherein modifying an operational state and/or operational mode of the second power converter stage comprises a change in number of phases enabled in the second power converter stage, a charge pump ratio of the second power converter stage, a switching frequency of the second power converter stage, a switching duty cycle of the second power converter stage, a switch segmentation of the second power converter stage, and a state variable of the second power converter stage.

33. The method of claim 23, wherein:
the first power converter stage is an inductive converter in combination with a gain element;
the second power converter stage is a charge pump;
the feedforward information is indicative of a change of available headroom of the gain element; and
the second power converter stage modifies its charge pump ratio in response to a change in the available headroom.

34. The method of claim 33, wherein a gain of the gain element is changed to compensate for modification of the charge pump ratio.

35. The method of claim 23, wherein:
the first power converter stage is an inductive converter;
the second power converter stage is a charge pump;
the feedforward information is indicative of a change of an error within a control loop of the inductive converter; and
the second power converter stage modifies its switching frequency in response to a change in available headroom.

36. The method of claim 23, wherein:
the first power converter stage is an inductive converter;
the second power converter stage is a charge pump;
the feedforward information is indicative of a change of a power consumption associated with the inductive converter; and
the second power converter stage modifies one or more of its charge pump ratio, number of active phases, switching frequency, and switch segmentation in response to a change in the power consumption.

37. The method of claim 36, further comprising modifying, by the inductive converter, one or more of its number of active phases, switching frequency, and switch segmentation in response to a change in the power consumption.

38. The method of claim 23, wherein:
the first power converter stage is a first inductive converter;
the second power converter stage is a second inductive converter;
the feedforward information is indicative of a change of a power limit setting associated with the first inductive converter; and
the second power converter stage modifies its power utilization to maintain power balance between the first inductive converter and the second inductive converter in response to a change in the power limit setting.

39. The method of claim 38, further comprising:
communicating headroom requirements of the second inductive converter to the first inductive converter; and
setting an output voltage of the first inductive converter in response to a change in the headroom requirements in order to maximize efficiency while maintaining sufficient headroom for the second inductive converter.

40. The method of claim 38, wherein the second inductive converter comprises an audio amplifier.

41. The method of claim 23, wherein:
the first power converter stage is a first inductive converter;
the second power converter stage is a second inductive converter;
the feedforward information is indicative of a change of an error associated within a control loop of the first inductive converter; and
the second power converter stage modifies its bandwidth in response to a change in the error.

42. The method of claim 41, further comprising:
communicating a second error associated with a second control loop of the second inductive converter from the second inductive converter to the first inductive converter; and
modifying the bandwidth of the first inductive converter in response to a change in the second error.

43. The method of claim 23, wherein:
the first power converter stage is an inductive converter;
the second power converter stage is a charge pump; and
the modification comprises a modification of a charge pump ratio of the charge pump.

44. The method of claim 23, wherein:
the first power converter stage is a charge pump;
the second power converter stage is an inductive converter; and
the modification comprises a modification of a state variable of the inductive converter.
